(19) United States
(12) Patent Application Publication
(10) Pub. No.: US 2019/0081208 A1
(43) Pub. Date: Mar. 14, 2019

(54) LIGHT EMITTING DEVICE AND LIGHT EMITTING DEVICE PACKAGE INCLUDING THE SAME

(71) Applicant: LG INNOTEK CO., LTD., Seoul (KR)

(72) Inventor: Byung Yeon CHOI, Seoul (KR)

(73) Assignee: LG INNOTEK CO., LTD., Seoul (KR)

(21) Appl. No.: 16/074,697

(22) PCT Filed: Feb. 2, 2017
(86) PCT No.: PCT/KR2017/001104

§ 371 Date: Aug. 1, 2018

(30) Foreign Application Priority Data
Feb. 2, 2016 (KR) 10-2016-0012663

(51) Int. Cl. H01L 33/14; H01L 33/32; H01L 33/06; H01L 33/10; H01L 33/62; H01L 33/36

(52) U.S. Cl. CPC H01L 33/145; H01L 33/325; H01L 33/36; H01L 33/10; H01L 33/62; H01L 33/06

(57) ABSTRACT

An embodiment of a light emitting device includes a substrate; a first conductivity-type semiconductor layer disposed on the substrate; an active layer disposed on the first conductivity-type semiconductor layer, a plurality of quantum well layers and a plurality of quantum barrier layers being alternately stacked in the active layer; a second conductivity-type semiconductor layer disposed on the active layer; a contact layer disposed on the second conductivity-type semiconductor layer; a current spreading layer disposed on the contact layer; and a current blocking layer disposed on the second conductivity-type semiconductor layer, wherein the contact layer and/or the current spreading layer is formed to surround at least a portion of the current blocking layer and a maximum value of intensity of a diffracted X-ray beam when a Miller plane index is 400.

### TECHNICAL FIELD

Embodiments relate to a light emitting device and a light emitting device package including the same.

### BACKGROUND ART

The statements in this section merely provide background information related to embodiments and may not constitute prior art.

Group III-V compound semiconductors such as GaN and AlGaN have been widely used for electronic devices and optoelectronics thanks to many advantages thereof such as a wide-range and easily adjustable energy bandgap.

Particularly, a light emitting device, such as a light emitting diode LED) or a laser diode, using a Group III-V or II-VI compound semiconductor material may emit various colors, such as red, green, blue, and ultraviolet light, etc., thanks to advances in thin-film growth technology and development of materials for the device. The light emitting device may also emit white light with high efficiency using a fluorescent material or through combination of colors. The light emitting device has advantages of lower power consumption, semi-permanent lifespan, rapid response time, safety, and environmentally friendliness, as compared with conventional light sources, such as a fluorescent lamp and an incandescent lamp.

Thus, the light emitting device has been increasingly applied to a transmission module for light communication means, an LED backlight which replaces a cold cathode fluorescence lamp (CCFL) constituting a backlight of a liquid crystal display (LCD) device, a white LED lighting apparatus which may replace a fluorescent lamp or an incandescent lamp, a head lamp of a vehicle, and a signal light.

Studies on the light emitting device for smooth operation and increased energy efficiency have been continuously conducted. For example, development of a light emitting device having a low operating voltage and high light output has been demanded.

### DISCLOSURE

### Technical Problem

Therefore, embodiments provide a light emitting device having a low operating voltage and high light output.

The technical objects that can be achieved through the present invention are not limited to what has been particularly described hereinabove and other technical objects not described herein will be more clearly understood by persons skilled in the art from the following detailed description.

### Technical Solution

In one embodiment, a light emitting device may include a substrate; a first conductivity-type semiconductor layer disposed on the substrate; an active layer disposed on the first conductivity-type semiconductor layer, a plurality of quantum well layers and a plurality of quantum barrier layers being alternately stacked in the active layer; a second conductivity-type semiconductor layer disposed on the active layer; a contact layer disposed on the second conductivity-type semiconductor layer; a current spreading layer disposed on the contact layer; and a current blocking layer disposed on the second conductivity-type semiconductor layer, wherein the contact layer and/or the current spreading layer is formed to surround at least a portion of the current blocking layer and has a maximum value of intensity of a diffracted X-ray beam when a Miller plane index is 400.

In another embodiment, a light emitting device may include a reflective layer; a substrate disposed on the reflective layer; a first conductivity-type semiconductor layer disposed on the substrate; an active layer disposed on the first conductivity-type semiconductor layer; a second conductivity-type semiconductor layer disposed on the active layer; a contact layer disposed on the second conductivity-type semiconductor layer; and a current spreading layer disposed on the contact layer and formed of indium tin oxide (ITO) material; a passivation layer disposed on the current spreading layer; a first electrode disposed on the first conductivity-type semiconductor layer; a second electrode disposed on the second conductivity-type semiconductor layer; and a current blocking layer disposed between the second conductivity-type semiconductor layer and the second electrode.

In one embodiment, a light emitting device package may include a body including a cavity; a lead frame installed on the body; and the light emitting device electrically connected to the lead frame.

### Advantageous Effects

In the embodiments, the contact layer serves to smoothly inject holes from the second conductivity-type semiconductor layer to the active layer, so that the light emitting device of the embodiments can lower an operating voltage and increase light output.

In the embodiments, the current spreading layer of the ITO material having a non-stoichiometric structure decreases current resistance so that current supplied from the second electrode is evenly spread to the current spreading layer and, as a result, an operating voltage of the light emitting device is lowered and light output of the light emitting device is raised.

### DESCRIPTION OF DRAWINGS

FIG. 1a is a sectional view of a light emitting device according to an embodiment.

FIG. 1b is a sectional view of the light emitting device including a passivation layer having a structure different from FIG. 1a.

FIG. 2 is a schematic plane view of the light emitting device according to the embodiment.

FIG. 3 is an enlarged view of a portion A of FIGS. 1a and 1b.

FIG. 4 is an enlarged view of a portion B of FIGS. 1a and 1b.

FIG. 5 is an enlarged view of a portion C of FIGS. 1a and 1b.

FIGS. 6 and 7 are graphs showing experimental results of X-ray diffraction for explaining the light emitting device according to the embodiment.

FIGS. 8 and 9 are graphs showing an experimental result of Table 2.

FIGS. 10 and 11 are graphs showing an experimental result of Table 3.

FIG. 12 is a view showing a light emitting device package 10 according to an embodiment.

### BEST MODE

Reference will now be made in detail to embodiments, examples of which are illustrated in the accompanying drawings. While the disclosure is susceptible to various modifications and alternative forms, specific embodiments thereof are shown by way of example in the drawings. However, the disclosure should not be construed as limited to the embodiments set forth herein, but on the contrary, the disclosure is to cover all modifications, equivalents, and alternatives falling within the spirit and scope of the embodiments.

While terms, such as “first”, “second”, etc., may be used to describe various components, such components must not be limited by the above terms. The above terms are used only to distinguish one component from another. In addition, terms particularly defined in consideration of construction and operation of the embodiments are used only to describe the embodiments and do not define the scope of the embodiments.

In the description of the embodiments, it will be understood that, when an element is referred to as being formed “on” or “under” another element, it can be directly “on” or “under” the other element or be indirectly formed with intervening elements therebetween. It will also be understood that, when an element is referred to as being “on” or “under,” “under the element” as well as “on the element” can be included based on the element.

As used herein, relational terms, such as “on”/“upper part”/“above”, “under”/“lower part”/“below”, and the like, are used solely to distinguish one entity or element from another entity or element without necessarily requiring or implying any physical or logical relationship or order between such entities or elements.

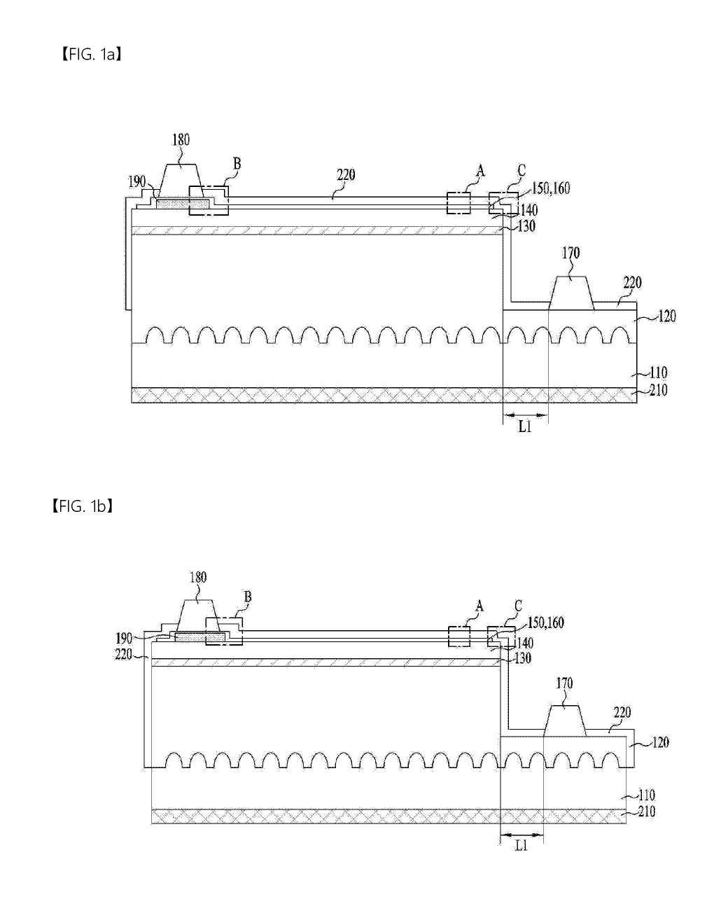

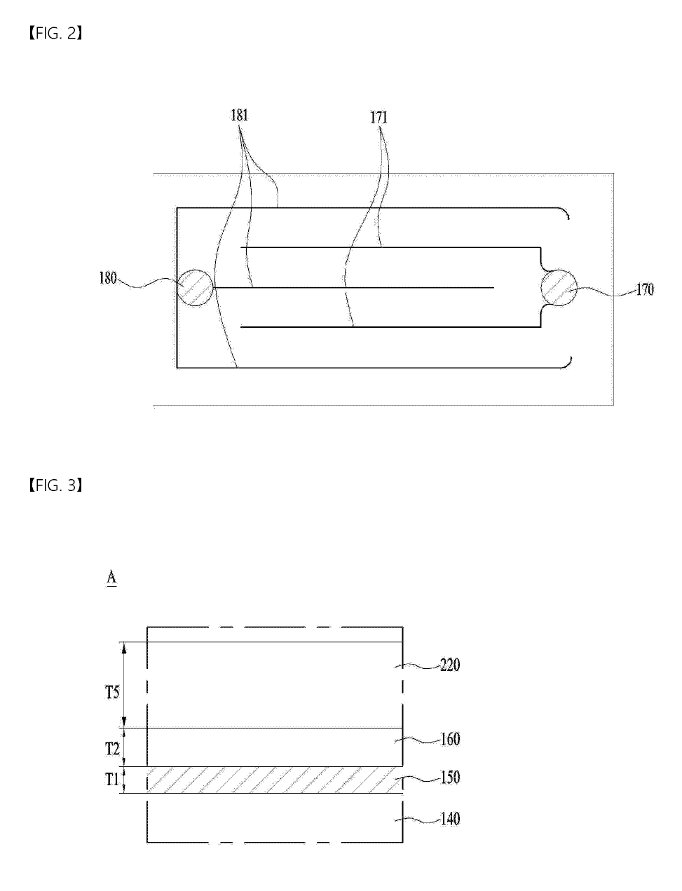

FIG. 1a is a sectional view of a light emitting device according to an embodiment. FIG. 1b is a sectional view of the light emitting device including a passivation layer 220 having a structure different from FIG. 1a. FIG. 2 is a schematic plane view of the light emitting device according to the embodiment.

The light emitting device of the embodiment may include a substrate 110, a first conductivity-type semiconductor layer 120, an active layer 130, a second conductivity-type semiconductor layer 140, a contact layer 150, a current spreading layer 160, a first electrode 170, a second electrode 180, a current blocking layer 190, a reflective layer 210, and a passivation layer 220.

The first conductivity-type semiconductor layer 120, the active layer 130, and the second conductivity-type semiconductor layer 140 may constitute a light emitting structure.

The substrate 110 may support the light emitting structure. The substrate 110 may be any of a sapphire substrate, a silicon (Si) substrate, a zinc oxide (ZnO) substrate, and a nitride semiconductor substrate, or may be a template substrate on which at least one of GaN, InGaN, AlGaN, or AlInGaN is stacked.

The light emitting structure may be disposed on the substrate 110 and serve to generate light. In this case, a difference in lattice constant and coefficient of thermal expansion between the substrate 110 and the light emitting structure may cause stress around a boundary surface between the substrate 110 and the light emitting structure.

To relieve such stress, a buffer layer (not shown) may be interposed between the substrate 110 and the light emitting structure. In addition, to improve crystallinity of the first conductivity-type semiconductor layer 120, an undoped semiconductor layer (not shown) may be interposed between the substrate 110 and the light emitting structure. Notably, an N-vacancy may be formed in a manufacturing process and, then, doping may be unintentionally performed.

Herein, the buffer layer may be grown at a low temperature. The buffer layer may be a GaN layer or an AlN layer but embodiments are not limited thereto. The undoped semiconductor layer may be the same as the first conductivity-type semiconductor layer 120 except that the undoped semiconductor layer has lower electrical conductivity than the first conductivity-type semiconductor layer 120 because the undoped semiconductor layer is not doped with an n-type dopant.

As illustrated in FIG. la, the first electrode 170 may be disposed on an exposed stepped portion of the first conductivity-type semiconductor layer 120 and the second electrode 180 may be disposed on an upper exposed portion of the second conductivity-type semiconductor layer 140. If current is applied through the first electrode 170 and the second electrode 180, the light emitting device of the embodiment may emit light.

Although FIGS. 1a and 1b show light emitting devices having a horizontal structure, light emitting devices having a vertical structure or a flip chip structure may also be provided.

As described above, the light emitting structure may include the first conductivity-type semiconductor layer 120, the active layer, 130 and the second conductivity-type semiconductor layer 140.

The first conductivity-type semiconductor layer 120 may be disposed on the substrate 110 and may be formed of a nitride semiconductor for example.

That is, the first conductivity-type semiconductor layer 120 may be formed of a material selected from semiconductor materials having a composition of InₓAl_{y}Ga_{1-x-y}N (0≤x≤1, 0≤y≤1, and 0≤x+y≤1), for example, GaN, AlN, AlGaN, InGaN, InN, InAlGaN, and AlInN, and may be doped with an n-type dopant such as Si, Ge, Sn, Se, or Te.

The active layer 130 may be disposed on the first conductivity-type semiconductor layer 120 and generate light by energy created during recombination of electrons and holes supplied from the first conductivity-type semiconductor layer 120 and the second conductivity-type semiconductor layer 140, respectively.

The active layer 130 may be formed of a compound semiconductor, for example, a Group III-V or II-VI compound semiconductor, and may have a single quantum well structure, a multi-quantum well structure, a quantum wire structure, or a quantum dot structure.

When the active layer 130 has a quantum well structure, the active layer 130 may have a single or multi-quantum well structure including a quantum well layer having a composition of InₓAl_{y}Ga_{1-x-y}N (0≤x≤1, 0≤y≤1, and 0≤x+y≤1) and a quantum barrier layer having a composition of InₐAl_{b}Ga_{1-a-b}N (0≤a≤1, 0≤b≤1, and 0≤a+b≤1).

In this case, the energy bandgap of the quantum well layer may be less than the energy bandgap of the quantum barrier layer. When the active layer 130 of the embodiment has a multi-quantum well structure, the active layer 130 may include a structure in which a plurality of quantum well layers and a plurality of quantum barrier layers may be alternately stacked.

The second conductivity-type semiconductor layer 140 may be disposed on the active layer 130. The second conductivity-type semiconductor layer 140 may be formed of, for example, a nitride semiconductor.

That is, the second conductivity-type semiconductor layer 140 may be formed of a material selected from semiconductor materials having a composition of InₓAl_{y}Ga_{1-x-y}N (0≤x≤1, 0≤y≤1, and 0≤x+y≤1), for example, GaN, AlN, AlGaN, InGaN, InN, InAlGaN, and AlInN, and may be doped with a p-type dopant such as Mg, Zn, Ca, Sr, or Ba.

The contact layer 150 may be disposed on the second conductivity-type semiconductor layer 140 and may serve to improve contact performance between the current spreading layer 160 disposed thereon and the second conductivity-type semiconductor layer 140 disposed thereunder, so that holes may be smoothly injected into the active layer 130 from the second conductivity-type semiconductor layer 140.

That is, the contact layer 150 is disposed at a boundary surface between the current spreading layer 160 and the first conductivity-type semiconductor layer 120 and serves to reduce electrical resistance that may be generated at the boundary surface between the current spreading layer 160 and the second conductivity-type semiconductor layer 140, so that current supplied to the current spreading layer 160 may smoothly flow into the second conductivity-type semiconductor layer 140.

In this way, current may smoothly flow into the second conductivity-type semiconductor layer 140 and, then, a large quantity of holes may be generated from the second conductivity-type semiconductor layer 140 and may be injected into the active layer 130.

In the embodiment, the contact layer 150 may cause holes to be smoothly injected from the second conductivity-type semiconductor layer 140 into the active layer 130 so that an operation voltage is lowered and light output is raised in the light emitting device according to the embodiment.

The contact layer 150 may be formed of, for example, at least one material of indium tin oxide (ITO), NiO, or NiAu and may be formed as a structure having low electrical resistance.

To form the contact layer 150 having a structure of low electrical resistance, it may be proper to raise porosity of, for example, an oxygen (O₂) component. Oxygen may be included in components constituting the contact layer 150 and oxygen tends to raise electrical resistance of the contact layer 150.

Therefore, to reduce electrical resistance of the contact layer 150, it may be proper to form the contact layer 150 to have a non-stoichiometric structure in which there is a lack of an oxygen component rather than a stoichiometric structure having high oxygen porosity.

The non-stoichiometric structure which is lacking in an oxygen component may be achieved using a process gas including argon gas without mixing oxygen during deposition of the contact layer 150.

That is, oxygen is not included in the process gas so that only an oxygen component included in a source material may be included in the contact layer 150. Since there is no additional supply of oxygen through the process gas, the contact layer 150 may be formed as the non-stoichiometric structure which is lacking in an oxygen component.

However, to raise light transmittance of the contact layer 150, for example, a process gas in which oxygen and/or hydrogen (H₂) are mixed with argon gas may be used. When an X-ray diffraction test of the contact layer 150 is performed, a crystal structure having a maximum value of intensity of a diffracted beam may be provided at a Miller plane index of 222 or 400.

The current spreading layer 160 may be disposed on the contact layer 150 and may be electrically connected to the second electrode 180. The current spreading layer 160 may play the role as current applied from the second electrode 180 may be evenly spread over the entire surface of the second conductivity-type semiconductor layer 140.

If current applied to the second conductivity-type semiconductor layer 140 through the second electrode 180 is not evenly spread, current may be concentrated at a specific portion of the second conductivity-type semiconductor layer 140. As a result, holes injected from the second conductivity-type semiconductor layer 140 into the active layer 130 may be concentrated in a specific portion of the active layer 130.

Concentration of hole injection may remarkably deteriorate light output of the light emitting device. To prevent this, it may be proper to evenly spread current over the entire surface of the second conductivity-type semiconductor layer 140 through the current spreading layer 160.

The current spreading layer 160 may be formed of ITO. As described above, the electrical resistance of the current spreading layer 160 needs to be reduced as described above on the contact layer 150.

Therefore, since oxygen among components constituting the current spreading layer 160 tends to raise electrical resistance, in order to reduce the electrical resistance of the current spreading layer 160, it may be proper to form the current spreading layer 160 to have a non-stoichiometric structure which is lacking in an oxygen component rather than a stoichiometric structure having high oxygen porosity. A method of forming the non-stoichiometric structure which is lacking in an oxygen component will be described in detail later on.

The current blocking layer 190 may be disposed on the second conductivity-type semiconductor layer 140, i.e., between the second conductivity-type semiconductor layer 140 and the second electrode 180. Herein, an area of the current blocking layer 190 may be formed to be larger than an area of the second electrode 180.

The contact layer 150 and/or the current spreading layer 160 may be provided to surround at least a portion of the current blocking layer 190. For example, referring to FIG. 4, the contact layer 150 and/or the current spreading layer 160 may be formed to surround the upper surface of the current blocking layer 190 and/or the side surfaces of the current blocking layer 190.

The current blocking layer 190 may serve to prevent current applied from the second electrode 180 from being concentrated in a portion facing the second electrode 180 out of the second conductivity-type semiconductor layer 140.

This is because the current blocking layer 190 blocks current from immediately flowing into the second conductivity-type semiconductor layer 140 from the second electrode 180. To this end, the current blocking layer 190 may be formed of, for example, an electrical insulating material.

The current blocking layer 190 may prevent current from being concentrated at a specific portion of the second conductivity-type semiconductor layer 140 and, thus, prevent holes injected from the second conductivity-type semiconductor layer 140 into the active layer 130 from being concentrated at a specific portion of the active layer 130, so that deterioration of light output of the light emitting device of the embodiment may be prevented.

That is, the current blocking layer 190 may serve to evenly spread current, which may be concentrated at a portion facing the second electrode 180 in a vertical direction, over the current spreading layer 160.

As shown in FIGS. 1a and 1b, a mesa in which the second electrode 180 is disposed may be formed in the light emitting device and a distance L1 from the mesa to the first electrode 170 may be, for example, 3 μm to 10 μm.

Herein, the mesa represents a protrusion portion in the light emitting device and the distance L1 represents a distance from the side surface of the first conductivity-type semiconductor layer 120 of the mesa to a point of the first electrode 170 which is nearest the side surface of the first conductivity-type semiconductor layer 120.

As shown in FIG. 2, the second electrode 180 may include a second branch electrode 181 formed on the current spreading layer 160 and the first electrode 170 may include a first branch electrode 171 formed on the first conductivity-type semiconductor layer 120.

Notably, a portion in which the first branch electrode 171 is formed may be formed to have a structure in which the current spreading layer 160, the second conductivity-type semiconductor layer 140, and the active layer 130 may be etched in a vertical direction, in order for the first branch electrode 171 not to be electrically connected to the current spreading layer 160, the second conductivity-type semiconductor layer 140, and the active layer 130.

In this case, the current blocking layer 190 may also be formed in a portion facing the second branch electrode 181 in a vertical direction. This serves to evenly spread current over the current spread layer 160 by preventing current from concentratively flowing through the first branch electrode 171 into the second conductivity-type semiconductor layer 140 which faces the first branch electrode 171 in a vertical direction.

A distance from the mesa to the first branch electrode 171 may be less than the distance L1 from the mesa to the first electrode 170.

A reflective layer 210 may be disposed under the substrate 110 and may serve to improve luminous efficiency of the light emitting device. That is, a part of light emitted from the active layer 130 may be emitted through the lower part of the substrate 110. In considering that, the reflective layer 210 may be disposed under the substrate 110 so as to reflect light emitted through the lower part of the substrate 110 and transmit light in an upward direction of the light emitting device. As a result, luminous efficiency of the light emitting device may be improved.

The reflective layer 210 may be a distributed Bragg reflective layer having a multilayer structure in which at least two layers having different refractive indexes are alternately stacked at least one time. The reflective layer 210 reflects light introduced from the light emitting structure.

That is, the reflective layer 210 may have a structure in which a first layer having a relatively high refractive index and a second layer having a relatively low refractive index are alternately stacked. In this case, reflectivity of the reflective layer 210 may differ according to difference between the reflective indexes of the first and second layers and thickness of each of the first and second layers.

At least a part of the passivation layer 220 may be disposed on the current spreading layer 160. Specifically, as shown in FIG. 1a, the passivation layer 220 may be disposed at the upper surface of the current spreading layer 160 and the upper surface of the stepped portion of the first conductivity-type semiconductor layer 120.

In addition, the passivation layer 220 may be disposed at at least a portion of side surfaces of the first conductivity-type semiconductor layer 120, the active layer 130, the second conductivity-type semiconductor layer, and the current spreading layer 160.

The passivation layer 220 having the above-described structure may serve to protect each layer constituting the light emitting device. Particularly, the passivation layer 220 may serve to prevent electrical short between the first conductivity-type semiconductor layer 120 and the second conductivity-type semiconductor layer 140.

As an embodiment, the passivation layer 220 may be formed not to cover a portion of the side surfaces of the first conductivity-type semiconductor layer 120 as shown in FIG. 1a. As another embodiment, the passivation layer 220 may be formed to cover all of the side surfaces of the first conductivity-type semiconductor layer 120 as shown in FIG. 1b.

The thickness of the passivation layer 220 may be about 100 nm. According to the thickness of the passivation layer 220, a refractive index of the light emitting structure may vary. Therefore, luminous efficiency of the light emitting device, i.e., light extraction efficiency of the light emitting device, may differ according to variation in thickness of the passivation layer 220.

As an embodiment, the passivation layer 220 may be provided to expose the side surfaces of the first electrode and the second electrode as shown in FIGS. 1a and 1b. As another embodiment, the passivation layer 220 may be provided to cover the side surfaces of the first electrode and the second electrode. As still another embodiment, the passivation layer 220 may be provided such that the side surfaces of the passivation layer 220 are separated from the side surfaces of the first electrode and the second electrode by a predetermined distance. However, embodiments are not limited thereto.

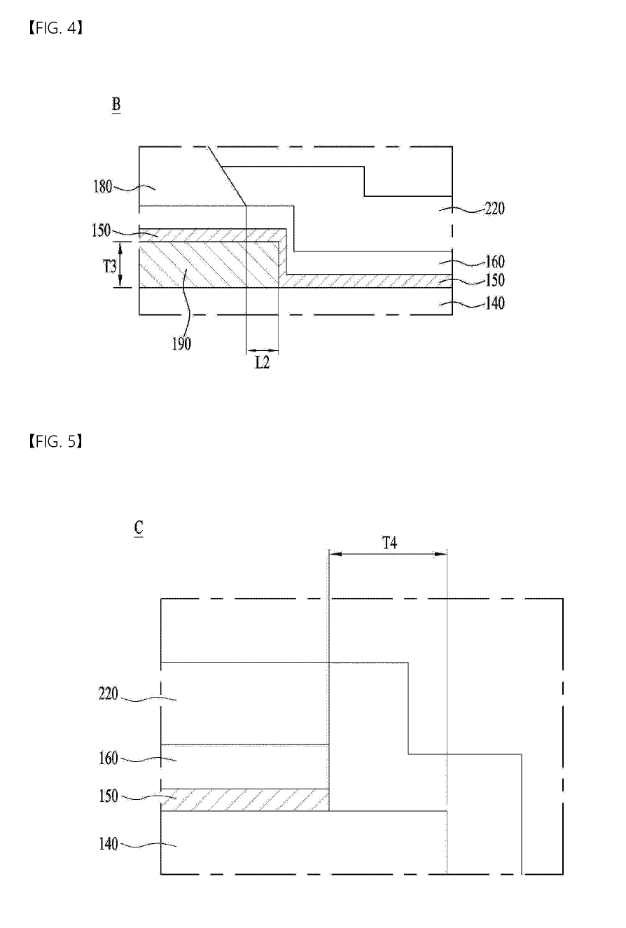

FIG. 3 is an enlarged view of a portion A of FIGS. 1a and 1b. As shown in FIG. 3, the current spreading layer 160 may be stacked on the contact layer 150.

The contact layer 150 may be formed to have a thickness T1 of 1 nm to 5 nm, for example. The current spreading layer 160 may be formed to have a thickness T2 of 20 nm to 70 nm, for example. However, the thickness of the contact layer 150 at a portion in which the current blocking layer 190 is disposed may be different from the above thickness T1.

The ratio of the thickness of the current blocking layer 190 to the total thickness of the contact layer 150 and the current spreading layer 160 may be, for example, 2:1 to 5:1 (thickness of the current blocking layer 190: total thickness). However, embodiments are not limited thereto.

The ratio of thickness of the current spreading layer 160 to the thickness of the contact layer 150 may be, for example, 6:1 to 10:1 (thickness of the current spreading layer 160: thickness of the contact layer 150). However, embodiments are not limited thereto.

If the thickness of the current spreading layer 160 is less than 20 nm, electrical resistance of the current spreading layer 160 is raised and then an operation voltage of the light emitting device is also raised. This may have an adverse effect on performance of the light emitting device.

If the thickness T2 of the current spreading layer 160 exceeds 70 nm, light transmittance of the current spreading layer 160 is reduced and then light output of the light emitting device is reduced. This may an adverse effect on the performance of the light emitting device.

The passivation layer 220 may be provided with a thickness T5 of about 100 nm as described above and may be thicker than the contact layer 150 and/or the current spreading layer 160.

The ratio of the thickness T5 of the passivation layer 220 to the thickness T2 of the current spreading layer 160 may be, for example, T5:T2=1.4:1 to 5:1.

As described above, the current spreading layer 160 may be formed of ITO. To reduce electrical resistance, the current spreading layer 160 may have a non-stoichiometric structure which is lacking in an oxygen component.

The current spreading layer 160 may be formed in a stack by, for example, plasma vacuum deposition. The non-stoichiometric structure of the current spreading layer 160 may be formed by a scheme described below.

The current spreading layer 160 may be formed by deposition under an argon (Ar) gas atmosphere. That is, a deposition process for the current spreading layer 160 may be performed at a high temperature by spraying a source material constituting the current spreading layer 160 on the contact layer 150 through a process gas in a plasma state. Such plasma vacuum deposition may be performed in a vacuum chamber.

One method of plasma vacuum deposition includes sputtering. Sputtering may be performed by forming a thin film by ejection of atoms and/or molecules from a target material when ions included in the process gas in a plasma state apply shock to the source material, i.e., the target material.

Sputtering is excellent in adhesion force of a thin film and may form a thin film having uniform thickness and uniform density because the target material is widely distributed in a vacuum chamber. The thin film formed by sputtering has the advantages such as superior step coverage and facilitative deposition of an oxide-series material.

The process gas may include an inert gas, for example, argon. Generally, a mixture of argon and oxygen gases or a mixture of argon, oxygen, and hydrogen gases may be used as the process gas for depositing ITO.

However, when a gas mixed with oxygen is used as the process gas, oxygen is sufficiently supplied to the deposited ITO. Then, the ITO in which oxygen is stoichiometrically contained may be stacked.

The ITO of the stoichiometric structure has characteristics of high electrical resistance due to oxygen contained therein. Accordingly, the current spreading layer 160 of the embodiment formed of the ITO material may use argon as the process gas in order to reduce electrical resistance thereof.

When argon is used, oxygen porosity of the current spreading layer 160 may increase. Since oxygen pores serve as electron carriers in the current spreading layer 160, the electrical resistance of the current spreading layer 160 may be reduced.

As another embodiment, the process gas may solely use an inert gas which does not include oxygen or a mixture of inert gases of various types.

When the current spreading layer 160 of the ITO material is formed using the process gas including argon without containing oxygen, the current spreading layer 160 may be formed as a non-stoichiometric structure which is lacking in oxygen in terms of stoichiometry.

In this case, the current spreading layer 160 may have a maximum value of intensity of a diffracted beam when a Millar plane index is 400 in an X-ray diffraction experiment.

Table 1 shows experimental result values of resistance of the current spreading layer 160 of the ITO material of the embodiment. In Table 1, a comparative sample refers to a sample when the current spreading layer 160 is formed using a process gas in which argon is mixed with oxygen and an embodiment sample refers to a sample when the current spreading layer 160 is formed using a process gas including only argon. Herein, resistance refers to sheet resistance. Therefore, the unit of resistance is Ω/□.

Experimental values of samples have been measured when the thickness T2 of the current spreading layer 160 is about 40 nm, 50 nm, and 60 nm. Experiments were conducted multiple times and the resistance value is an average of values obtained through multiple experiments.

TABLE 1

| Sample/ITO thickness | Resistance value | Light transmittance |
|---|---|---|
| (nm) | (Ω/□) | (%) |
| Comparative sample/40 | 78.32 | 94.39 |
| Embodiment sample/40 | 50.83 | 94.92 |
| Comparative sample/50 | 53.25 | 92.84 |
| Embodiment sample/50 | 32.55 | 92.39 |
| Comparative sample/60 | 49.03 | 92.29 |
| Embodiment sample/60 | 24.01 | 92.24 |

Referring to Table 1, it may be appreciated that the resistance values of the embodiment samples are remarkably lower than resistance values of the comparative samples. That is, the current spreading layer 160 formed by using the process gas including only argon has a remarkably lower electrical resistance value than the current spreading layer 160 of ITO material formed by using the process gas including a mixture of argon and oxygen. Therefore, it may be appreciated that current supplied from the second electrode 180 can be more evenly spread over the current spreading layer 160 when the current spreading layer 160 of the embodiment is used.

In terms of light transmittance, there is little difference in light transmittance between the comparative sample and the embodiment sample, with respect the current spreading layer 160 of the same thickness. Accordingly, it may be clearly appreciated that the electrical resistance of the current spreading layer 160 of the ITO material of the non-stoichiometric structure according to the embodiment is greatly reduced but there is little change in light transmittance.

That is, when the current spreading layer 160 is formed using the process gas including only argon, since electrical resistance is reduced and light transmittance is not reduced, light output of the light emitting device can be raised.

In the embodiment, since the current spreading layer 160 of the ITO material of the non-stoichiometric structure has the reduced current resistance, current supplied from the second electrode 180 is evenly spread over the current spreading layer 160. As a result, the operating voltage of the light emitting device is lowered and light output of the light emitting device is raised.

FIG. 4 is an enlarged view of a portion B of FIGS. 1a and 1b. In the embodiment, the current blocking layer 190 may be formed to have a thickness T3 of 90 nm to 150 nm, for example.

As shown in FIG. 4, the contact layer 150 and the current spreading layer 160 may be sequentially stacked in an upward direction from the bottom between the current blocking layer 190 and the second electrode 180.

In this case, to secure a space in which the current blocking layer 190 is disposed, the thickness of each of side surfaces of the contact layer 150 and the current spreading layer 160, that is, the thickness of each of side surfaces of the contact layer 150 and the current spreading layer 160 at the side surface of the current blocking layer 190, may be formed to be thin as compared with the thickness of each of other portions of the contact layer 150 and the current spreading layer 160.

In another embodiment, to secure a space in which the current blocking layer 190 is disposed, only the current spreading layer 160 may be formed between the current blocking layer 190 and the second electrode 180.

As described above, the area of the current blocking layer 190 may be greater than the area of the second electrode 180. Herein, a distance L2 between an end of the second electrode 180 and the current blocking layer 190 may be about 3 pm.

FIG. 5 is an enlarged view of a portion C of FIGS. 1a and 1b. That is, in a mesa region in which the second electrode is formed, a distance T4 between the side surface of the contact layer 150 and/or the current spreading layer 160 and the side surface of the second conductivity-type semiconductor layer 140 may be, for example,3 μm to 10 μm.

If the distance T4 is less than 3 μm, electron hopping may occur in the side surface of the current spreading layer 160, the contact layer 150, and/or the side surface of the second conductivity-type semiconductor layer 140 and, thus, current leakage may occur.

If the distance T4 exceeds 10 pm, the operating voltage of the light emitting device may be raised and light output of the light emitting device may be reduced.

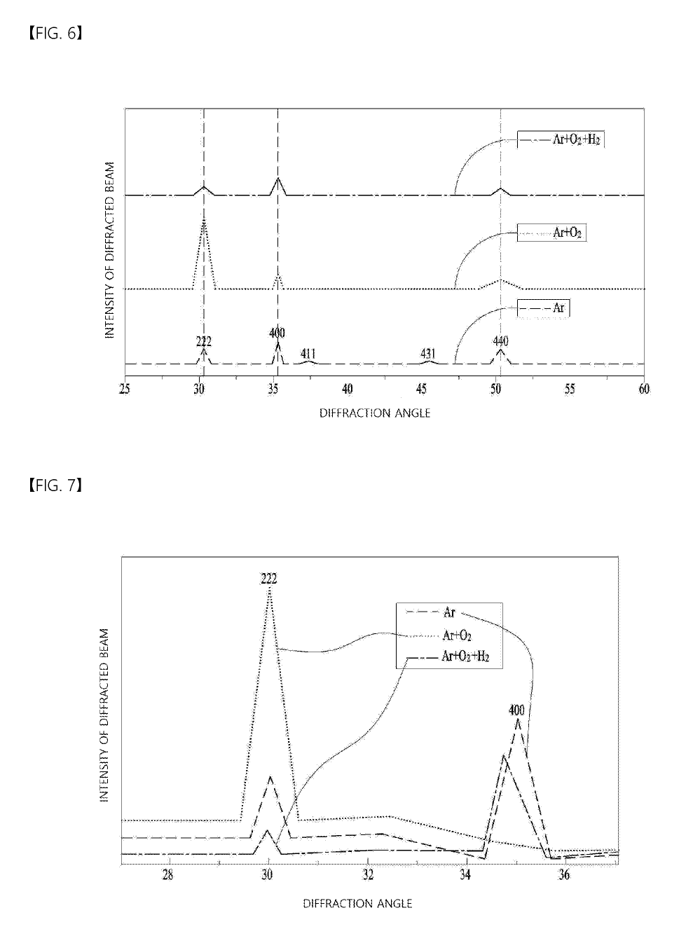

FIGS. 6 and 7 are graphs showing experimental results of X-ray diffraction for explaining the light emitting device according to the embodiment. The X-ray diffraction experiment is a result of analyzing the type of a diffracted beam by irradiating the current spreading layer 160 with an X-ray beam.

In the graphs, the horizontal axis denotes a diffraction angle (°) of a diffracted X-ray beam by irradiating the current spreading layer 160 with an X-ray beam and the vertical axis denotes intensity (a.u.) of a diffracted X-ray beam.

In FIGS. 6 and 7, the cases in which a process gas includes argon, the process gas includes a mixture of argon and oxygen, and the process gas includes a mixture of argon, oxygen, and hydrogen are actually shown. FIG. 6 actually shows intensities of a diffracted beam in the respective cases. FIG. 7 shows the approximately matched non-peak values of intensities of diffracted beams in the respective cases in order to compare peak values of intensities of diffracted beams in the respective cases.

In the drawings, numbers 222, 400, and 440 denote Miller plane indexes. The Miller plane indexes indicate specific crystal planes of the current spreading layer 160 which is a target of experimentation. Accordingly, when peak values of intensities of diffracted beams differ in portions in which Miller plane indexes are equal, this may mean that a crystal structure differs.

Referring to FIGS. 6 and 7, the current spreading layer 160 formed by deposition under an Ar gas atmosphere may have plural peak values in intensity of a diffracted beam according to a Millar plane index in X-ray diffraction experiments.

Referring to FIG. 7, when the Miller plane index is 222, intensity of a diffracted beam has a peak value in the case in which the process gas is a mixture of argon and oxygen. When the Miller plane index is 400, intensity of a diffracted beam has a peak value in the case in which the process gas is argon. That is, in the embodiment, the current spreading layer 160 may have a maximum peak value of intensity of a diffracted beam when the Millar plane index is 400 in X-ray diffraction experiments.

Therefore, components of the process gas may be identified through a peak value distribution of intensity of a diffracted beam according to a Millar plane index in X-ray diffraction experiments for the current spreading layer 160.

As described above, when the current spread layer 1160 is deposited by a sputtering process using argon as the process gas, the current spreading layer 160 may be formed as a structure having high porosity of an oxygen component. Then, electrical resistance of the current spreading layer 160 is reduced so that current may be smoothly spread over the current spreading layer 160.

Tables 2 and 3 shows experimental values of an operating value and light output of a light emitting chip using the light emitting device of the embodiment. Each light emitting chip was tested given a rated output of 95 mA.

In Table 2, all light emitting chips have a size of 1200×600. Case 1 is the case in which the operating voltage and light output are measured in the center of the light emitting device and Case 2 is the case in which the operating voltage and light output are measured at a specific part separated from the center of the light emitting device. The light emitting device including the current spreading layer 160 of the ITO material having a thickness of about 40 nm was used.

Test 1 corresponds to a test when the current spreading layer 160 of a normal ITO material is used, i.e., when a mixture of argon and oxygen is used as the process gas and a light emitting device of a structure in which the contact layer 150 is not formed is used.

Test 2 corresponds to a test when the current spreading layer 160 of the ITO material of the embodiment is used, i.e., when argon gas is used as the process gas without oxygen and a light emitting device having a structure in which the contact layer 150 is formed is used.

TABLE 2

| | | Operating voltage | Light output |
|---|---|---|---|
| Case | Test | (V) | (mW) |
| Case 1 | Test 1 | 2.96 | 138.6 |
| | Test 2 | 2.94 | 140.2 |
| Case 2 | Test 1 | 2.95 | 138.8 |
| | Test 2 | 2.93 | 141.1 |

In Table 3, light emitting chips having a size of 1200×700 were used and the other conditions are the same as those described in Table 2.

TABLE 3

| | | Operating voltage | Light output |
|---|---|---|---|
| Case | Test | (V) | (mW) |
| Case 1 | Test 1 | 2.92 | 147.4 |
| | Test 2 | 2.90 | 149.0 |
| Case 2 | Test 1 | 2.92 | 148.5 |
| | Test 2 | 2.90 | 148.8 |

In view of a result of tests, the operation voltage in Test 2 is lower than the operating voltage of Test 1 and light output in Test 2 is higher than light output in Test 1.

Therefore, it may be appreciated that when the light emitting device of the embodiment in which the current spreading layer 160 of the ITO material of the non-stoichiometric structure is formed and the contact layer 150 is formed is used, the operating voltage of the light emitting device is lowered and light output of the light emitting device is raised as compared with the case in which the current spreading layer 160 of the ITO material of the stoichiometric structure is used and the contact layer 150 is not formed.

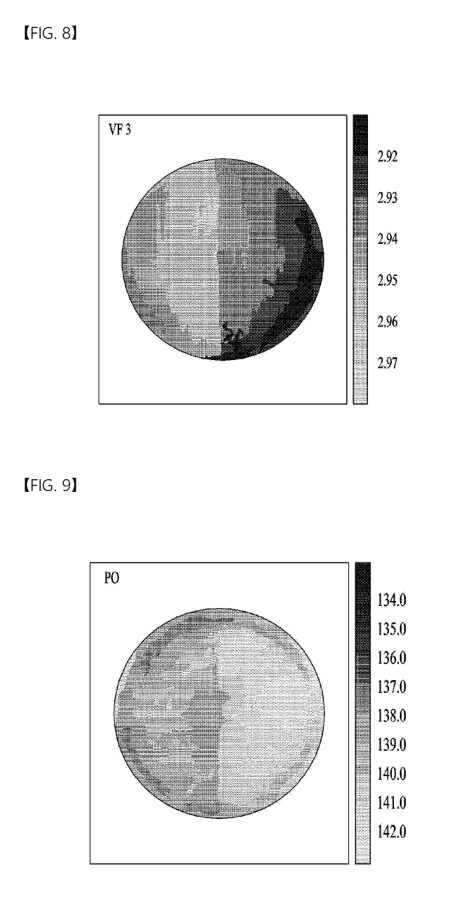

FIGS. 8 and 9 are graphs showing an experimental result of Table 2. VF3 shown in FIG. 8 denotes an operating voltage in volts (V) and Po denotes light output in milliwatts (mW). In the graphs represented by circles, a hemisphere of the left side represents Test 1 and a hemisphere of the right side represents Test 2. Since FIGS. and 9 shows halves of the entire region of the light emitting device, the graphs of FIGS. 8 and 9 include both Case 1 and Case 2.

Referring to FIG. 8 showing operating voltages, it can be appreciated that operating voltages in Test 2 are lower in entirety than operating voltages in Test 1. Referring to FIG. 9 showing light outputs, it can be appreciated that light outputs in Test 2 are higher in entirety than light outputs in Test 1.

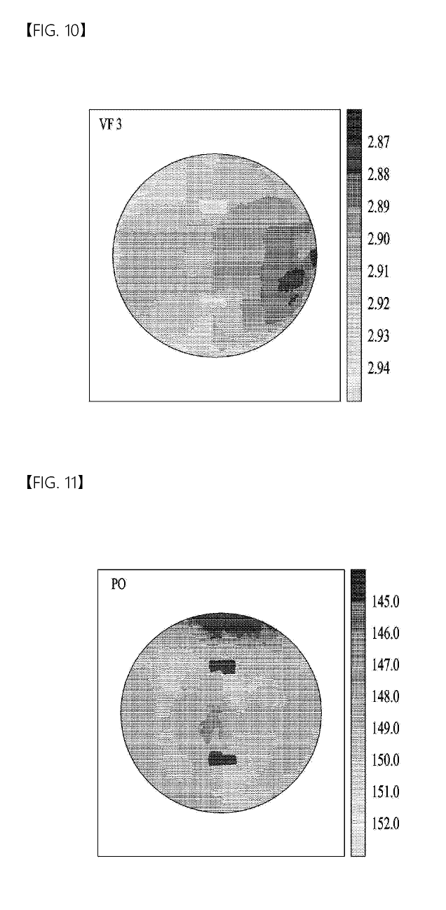

FIGS. 10 and 11 are graphs showing an experimental result of Table 3. Similar to FIGS. 8 and 9, in the graphs represented by circles, a hemisphere of the left side represents Test 1 and a hemisphere of the right side represents Test 2. The graphs of FIGS. 10 and 11 include both Case 1 and Case 2.

Referring to FIG. 10 showing operating voltages, it can be appreciated that operating voltages in Test 2 are lower in entirety than operating voltages in Test 1. Referring to FIG. 11 showing light outputs, it can be appreciated that light outputs in Test 2 are higher in entirety than light outputs in Test 1.

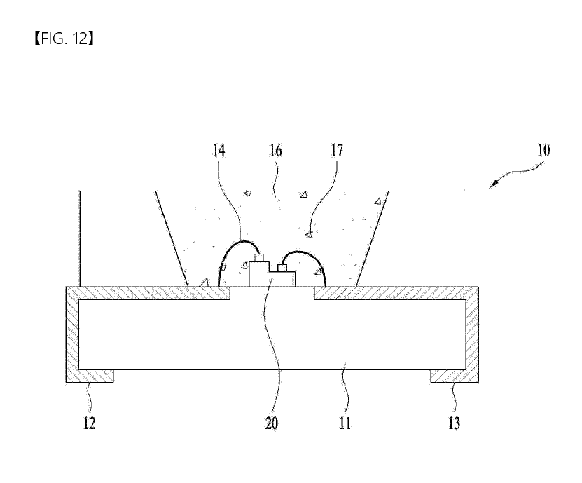

FIG. 12 is a view showing a light emitting device package 10 according to an embodiment.

The light emitting device package 10 according to the embodiment includes a body 11 including a cavity, first and second lead frames 12 and 13 installed on the body 11, the light emitting device 20 of the above-described embodiment installed on the body 11 and electrically connected to the first and second lead frames 12 and 13, and a molding portion 16 formed on the cavity.

The body 11 may include a silicone material, a synthetic resin material, or a metallic material. If the body 11 is formed of a conductive material such as a metallic material, the surface of the body 11 may be coated with an insulating layer although not shown in the drawing, so that electric short between the first and second lead frames 12 and 13 may be prevented. The cavity may be formed in the package body 11 and the light emitting device 20 may be disposed at the bottom surface of the cavity.

The first lead frame 12 and the second lead frame 13 are electrically isolated from each other and supply current to the light emitting device 20. The first lead frame 12 and the second lead frame 13 may increase luminous efficiency by reflecting light generated by the light emitting device 20 and dissipate heat generated by the light emitting device 20 to the exterior.

The light emitting device 20 may be formed according to the above-described embodiment. The light emitting device 20 may be electrically connected to the first lead frame 12 and the second lead frame 13 via wires 14.

The light emitting device 20 may be fixed to the bottom surface of the package body 11 by a conductive paste (not shown). The molding portion 16 may protect the light emitting device 20 by surrounding the light emitting device 20. Florescent substances 17 may be included in the molding portion 16 so that the fluorescent substances 17 may be excited by light of a first wavelength region emitted from the light emitting device 20 to emit light of a second wavelength region.

The light emitting device package 10 may include one or multiple light emitting devices according to the above-described embodiments, without being limited thereto.

The above-described light emitting device and light emitting device package may be used as a light source of a lighting system. For example, the light emitting device and the light emitting device package may be used for light emitting apparatuses such as an image display apparatus and a lighting apparatus.

When the light emitting device or the light emitting device package is used as a backlight unit for the image display apparatus, the light emitting device or the light emitting device package may be used as a backlight unit of an edge type or a backlight unit of a direct type. When the light emitting device or the light emitting device package is used for the lighting apparatus, the light emitting device or the light emitting device package may be used as a lamp instrument or a built-in type light source.

Although only several embodiments have been described above with regard to embodiments, various other embodiments are possible. The technical contents of the above-described embodiments may be combined in various forms unless they are incompatible and, thus, may be implemented in new embodiments.

### INDUSTRIAL APPLICABILITY

In the embodiments, the contact layer serves to smoothly inject holes from the second conductivity-type semiconductor layer to the active layer, so that the light emitting device of the embodiments can lower an operating voltage and raise light output. Therefore, the light emitting device is industrially applicable.

1.-10. (canceled)

11. A light emitting device comprising:
a substrate;
a first conductivity-type semiconductor layer disposed on the substrate;
an active layer disposed on the first conductivity-type semiconductor layer, a plurality of quantum well layers and a plurality of quantum barrier layers being alternately stacked in the active layer;
a second conductivity-type semiconductor layer disposed on the active layer;
a contact layer disposed on the second conductivity-type semiconductor layer;
a current spreading layer disposed on the contact layer; and
a current blocking layer disposed on the second conductivity-type semiconductor layer,
wherein the contact layer and/or the current spreading layer is formed to surround at least a portion of the current blocking layer and has a maximum value of intensity of a diffracted X-ray beam when a Miller plane index is 400.

12. The light emitting device according to claim 11, wherein the current spreading layer is formed by being deposited under an argon (Ar) gas atmosphere, has a plurality of peak values of intensity of a diffracted beam according to the Miller plane index in an X-ray diffraction experiment, and has a maximum peak value of intensity of a diffracted beam when the Miller plane index is 400.

13. The light emitting device according to claim 11, wherein a ratio of a thickness of the current blocking layer to a total thickness of the contact layer and current spreading layer is 2:1 to 5:1.

14. The light emitting device according to claim 11, wherein the contact layer is formed of at least one material of indium tin oxide (ITO), NiO, or NiAu.

15. The light emitting device according to claim 11, further comprising:
a first electrode disposed on the first conductivity-type semiconductor layer; and
a second electrode disposed on the second conductivity-type semiconductor layer,
wherein the current blocking layer is disposed between the second conductivity-type semiconductor layer and the second electrode.

16. The light emitting device according to claim 11, further comprising a reflective layer disposed under the substrate.

17. A light emitting device comprising:
a reflective layer;
a substrate disposed on the reflective layer;
a first conductivity-type semiconductor layer disposed on the substrate;
an active layer disposed on the first conductivity-type semiconductor layer;
a second conductivity-type semiconductor layer disposed on the active layer;
a contact layer disposed on the second conductivity-type semiconductor layer; and
a current spreading layer disposed on the contact layer and formed of indium tin oxide (ITO);
a passivation layer disposed on the current spreading layer;
a first electrode disposed on the first conductivity-type semiconductor layer;
a second electrode disposed on the second conductivity-type semiconductor layer; and
a current blocking layer disposed between the second conductivity-type semiconductor layer and the second electrode.

18. The light emitting device according to claim 17, wherein a mesa in which the second electrode is disposed is formed and a distance from a side surface of the first conductivity-type semiconductor layer of the mesa to a point of the first electrode which is nearest the side surface of the first conductivity-type semiconductor layer is 3 μm to 10 μm.

19. The light emitting device according to claim 17, wherein an area of the current blocking layer is greater than an area of the second electrode.

20. A light emitting device package comprising:
a body including a cavity;
a lead frame installed on the body; and
the light emitting device of claim 11, electrically connected to the lead frame.

21. The light emitting device according to claim 11, wherein the contact layer has a thickness of 1 nm to 5 nm.

22. The light emitting device according to claim 11, wherein the current spreading layer has a thickness of 20 nm to 70 nm.

23. The light emitting device according to claim 11, further comprising a passivation layer, at least a part of the passivation layer being disposed on the current spreading layer.

24. The light emitting device according to claim 23, wherein a ratio of a thickness of the passivation layer to a thickness of the current spreading layer is 1.4:1 to 5:1.

25. The light emitting device according to claim 11, wherein a distance between a side surface of the contact layer and/or the current spreading layer and a side surface of the second conductivity-type semiconductor layer is in the range of 3 μm to 10 μm.

26. The light emitting device according to claim 11, wherein the current spreading layer is formed of material of Indium Tin Oxide (ITO).

27. The light emitting device according to claim 26, wherein the current spreading layer has a non-stoichiometric structure.

28. The light emitting device according to claim 15, wherein the current spreading layer is disposed between the current blocking layer and the second electrode.

29. The light emitting device according to claim 15, wherein the current blocking layer has a thickness of 90 nm to 150 nm.

30. The light emitting device according to claim 17, wherein and a ratio of a thickness of the current spreading layer to a thickness of the contact layer is 6:1 to 10:1.
